(19) United States
(12) Patent Application Publication
(10) Pub. No.: US 2025/0305122 A1
(43) Pub. Date: Oct. 2, 2025

(54) COATED CONDUITS, RELATED SYSTEMS AND RELATED METHODS

(71) Applicant: ENTEGRIS, INC., Billerica (U)

(72) Inventors: Carlo Waldfried, Middleton, MA (US); Surendra Maharjan, Lowell, MA (US); Stephen Longo, Westford, MA (US); Bryan Hendrix, Danbury, CT (US); Jianan Hou, Lexington, MA (US)

(21) Appl. No.: 19/097,809

(22) Filed: Apr. 1, 2025

Related U.S. Application Data
(60) Provisional application No. 63/573,247, filed on Apr. 2, 2024.
(60) Provisional application No. 63/713,487, filed on Oct. 29, 2024.

(51) Int. Cl. C23C 16/44; C23C 16/455

(52) U.S. Cl. CPC C23C 16/4402; C23C 16/45561

(57) ABSTRACT

Systems comprising coated components are described. A system includes a first subsystem located in a sub-fabrication area of a semiconductor manufacturing facility, a second subsystem located in a fabrication area of the semiconductor manufacturing facility, and a conduit connecting the first subsystem to the second subsystem. The conduit has an inner surface and an outer surface and a protective coating formed on the inner surface. Coated components and related methods are also described.

### CROSS-REFERENCE TO RELATED APPLICATIONS

This application claims the benefit of and priority to U.S. Provisional Application No. 63/573,247 filed on Apr. 2, 2024 and to U.S. Provisional Application No. 63/713,487 filed on Oct. 29, 2024, each of which is incorporated herein in its entirety for all purposes.

### FIELD

The present disclosure relates to coated components, systems, and related methods used in the manufacture of a semiconductor device.

### BACKGROUND

During the manufacture of a semiconductor device, a process fluid (liquid or gas) is delivered to a process tool for completion of a process step used in the manufacture of the semiconductor device. Semiconductor manufacturing processes and the equipment and tools used in these processes are designed to mitigate defects in semiconductor devices.

### SUMMARY

Some embodiments relate to a system. In some embodiments, the system comprises a first subsystem. In some embodiments, the first subsystem is located in a sub-fabrication area of a semiconductor manufacturing facility. In some embodiments, the system comprises a second subsystem. In some embodiments, the second subsystem is located in a fabrication area of the semiconductor manufacturing facility. In some embodiments, the system comprises a conduit connecting the first subsystem to the second subsystem. In some embodiments, the conduit has an inner surface and an outer surface. In some embodiments, the conduit comprises an atomic layer deposition (ALD) coating. In some embodiments, the ALD coating covers the inner surface of the conduit. In some embodiments, when a gas or vapor is flowed through the conduit having the ALD coating, the gas or vapor collected at an outlet exhibits at least a 50% reduction in a metal impurity compared to when the gas or vapor is flowed through an uncoated conduit.

Some embodiments relate to a method. In some embodiments, the method comprises obtaining a conduit. In some embodiments, the conduit has an inlet, an outlet, an inner surface, and an outer surface. In some embodiments, the method comprises applying a pretreatment to at least a vapor-exposed surface portion of the inner surface of the conduit. In some embodiments, the method comprises forming an atomic layer deposition (ALD) coating on the vapor-exposed portion of the inner surface of the conduit. In some embodiments, the method comprises flowing a gas or vapor through the conduit, wherein the gas or vapor collected at the outlet exhibits at least a 50% reduction in a metal impurity compared to when the gas or vapor is flowed through an uncoated conduit.

Some embodiments relate to an article. In some embodiments, the article comprises a conduit. In some embodiments, the conduit is configured to connect a first subsystem to a second subsystem. In some embodiments, the first subsystem is located in a sub-fabrication area of a semiconductor manufacturing facility. In some embodiments, the second subsystem is located in a fabrication area of the semiconductor manufacturing facility. In some embodiments, the conduit has an inner surface and an outer surface. In some embodiments, the article comprises an atomic layer deposition (ALD) coating. In some embodiments, the ALD coating covers the inner surface of the conduit. In some embodiments, the ALD coating does not cover the outer surface of the conduit. In some embodiments, when a gas or vapor is flowed through the conduit having the ALD coating, the gas or vapor collected at an outlet exhibits at least a 50% reduction in a metal impurity compared to when the gas or vapor is flowed through an uncoated conduit.

### DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 is a flowchart of a method, according to some embodiments.

FIG. 2 is a schematic diagram of a system, according to some embodiments.

FIG. 3 is a schematic diagram of a system, according to some embodiments.

FIG. 4 is a schematic diagram of a system, according to some embodiments.

FIG. 5 is a schematic diagram of a system, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to a coated component and related systems and related methods, among other things. In some embodiments, the coated component is useful for connecting systems and/or subsystems of a facility, such as, for example and without limitation, a semiconductor manufacturing facility and the like, among others. For example, precursors stored outside a fabrication area are delivered along long heated gas lines, or more generally conduits, to fabrication areas containing deposition chambers. When the coated component is used for connecting a first subsystem of a semiconductor manufacturing facility to a second subsystem of the semiconductor manufacturing facility, the coating of the coated component enhances the quality of a vapor being delivered from the first subsystem to the second subsystem by sealing or encapsulating the conduit so as to minimize or avoid the release or entrainment of impurities and other contaminants into the vapor. That is, in some embodiments, the coated component is useful for minimizing a presence of defects in a film deposited on a semiconductor substrate.

Conventional coatings on components can have discontinuous coating areas where no coating is deposited. For at least these reasons, conventional coatings are not used for conduits of extended lengths, with high aspect ratios, because challenges associated with obtaining continuous, even, and/or uniform coatings become even more pronounced. Conventional coatings can also have properties that limit the scope of applications in which a conventional coating can be used. For example, conventional coatings can be brittle. In addition, when a coated component having a conventional coating is bent or otherwise manipulated, the bending and/or manipulating causes cracks to form in the coating. The bending and/or manipulating can also cause conventional coatings to delaminate or otherwise detach from the component.

Coated components are provided herein that overcome at least a portion of the challenges of conventional coated components. The coated components disclosed herein may comprise coatings on extended length conduits, with high aspect ratios. The coated components disclosed herein may comprise uniform coatings over an entire length of the conduit. In addition, the coated components disclosed herein may comprise coatings that are continuous, with minimal or no discontinuous coating areas. The coated components disclosed herein may minimize or eliminate the presence of defects caused by release of contaminants from the conduit into vapor supplied to deposition chambers during semiconductor manufacturing. In addition, the coated components disclosed herein may minimize or eliminate cracking and/or delamination of the coating from the conduit, when, for example and without limitation, the coated component is bend or manipulated during installation of the coated component at a facility.

According to various embodiments, the coated component can be a conduit and more particularly, a conduit have an extended length as defined herein.

As used herein, the term “conduit” refers to a structure through which a fluid flows. In some embodiments, the conduit is configured for vapor flow, throughout a length of the conduit, from an inlet of the conduit to an outlet of the conduit. For example, in some embodiments, the conduit comprises a channel. In some embodiments, the conduit comprises a pipe. In some embodiments, the conduit comprises a tube. In some embodiments, the conduit comprises a duct. In some embodiments, the conduit comprises a pipeline. In some embodiments, the conduit comprises a process fluid delivery line (e.g., a gas line, etc.). In some embodiments, the conduit comprises a manifold. It will be appreciated that the coated component may comprise structures other than conduits, without departing from the scope of this disclosure. The conduit, according to the various embodiments, can include a coating on an inner surface as described herein.

The conduit may have a length. In some embodiments, the length of the conduit is defined by a distance measured from an inlet of the conduit to an outlet of the conduit. For example, in some embodiments, a distance between an inlet of the conduit and an outlet of the conduit is 1 meter (m) to 1000 m, or longer, or any range or subrange between 1 m and 1000 m. In some embodiments, the distance between the inlet of the conduit and the outlet of the conduit is 2 m to 1000 m, 3 m to 1000 m, 4 m to 1000 m, 5 m to 1000 m, 10 m to 1000 m, 15 m to 1000 m, 20 m to 1000 m, 25 m to 1000 m, 30 m to 1000 m, 40 m to 1000 m, 50 m to 1000 m, 100 m to 1000 m, 200 m to 1000 m, 300 m to 1000 m, 400 m to 1000 m, 500 m to 1000 m, 600 m to 1000 m, 700 m to 1000 m, 800 m to 1000 m, 900 m to 1000 m, 1 m to 900 m, 1 m to 800 m, 1 m to 700 m, 1 m to 600 m, 1 m to 500 m, 1 m to 400 m, 1 m to 300 m, 1 m to 200 m, 1 m to 100 m, 1 m to 50 m, 2 m to 900 m, 2 m to 800 m, 2 m to 700 m, 2 m to 600 m, 2 m to 500 m, 2 m to 400 m, 2 m to 300 m, 2 m to 200 m, 2 m to 100 m, 2 m to 50 m, 3 m to 900 m, 3 m to 800 m, 3 m to 700 m, 3 m to 600 m, 3 m to 500 m, 3 m to 400 m, 3 m to 300 m, 3 m to 200 m, 3 m to 100 m, or 3 m to 50 m.

The conduit may have a cross-sectional width. For example, in some embodiments, the cross-sectional width refers to a diameter. In some embodiments, the cross-sectional width of the conduit is 5 mm to 1000 mm, or any range or subrange between 5 mm and 1000 mm. For example, in some embodiments, the cross-sectional width of the conduit is 5 mm to 900 mm, 5 mm to 800 mm, 5 mm to 700 mm, 5 mm to 600 mm, 5 mm to 500 mm, 5 mm to 400 mm, 5 mm to 300 mm, 5 mm to 200 mm, 5 mm to 100 mm, 10 mm to 1000 mm, 25 mm to 1000 mm, 50 mm to 5000 mm, 100 mm to 1000 mm, 200 mm to 1000 mm, 300 mm to 1000 mm, 400 mm to 1000 mm, 500 mm to 1000 mm, 600 mm to 1000 mm, 700 mm to 1000 mm, 800 mm to 1000 mm, or 900 mm to 1000 mm.

An aspect ratio of the conduit may comprise a ratio of a first dimension of the conduit to a second dimension of the conduit, wherein the first dimension and the second dimension are different. In some embodiments, the first dimension is a length of the conduit. In some embodiments, the second dimension is a cross-sectional width or diameter of the conduit. In some embodiments, the width of the cross-section of the conduit is an inner diameter of the conduit. In some embodiments, the width of the cross-section of the conduit is an outer diameter of the conduit. It will be appreciated that the aspect ratio may refer to other dimensions of the conduit, without departing from the scope of this disclosure.

A ratio of the length of the conduit to the width of a cross-section of the conduit is 2:1 to 1000:1, or any range or subrange between 2:1 and 1500:1. In some embodiments, the ratio of the length of the conduit to the width of the cross-section of the conduit is 2:1 to 1400:1, 2:1 to 1300:1, 2:1 to 1200:1, 2:1 to 1100:1, 2:1 to 1000:1, 2:1 to 900:1, 2:1 to 800:1, 2:1 to 700:1, 2:1 to 600:1, 2:1 to 500:1, 2:1 to 400:1, 2:1 to 300:1, 2:1 to 200:1, 2:1 to 100:1, 2:1 to 50:1, 100:1 to 1500:1, 200:1 to 1500:1, 300:1 to 1500:1, 400:1 to 1500:1, 500:1 to 1500:1, 600:1 to 1500:1, 700:1 to 1500:1, 800:1 to 1500:1, 900:1 to 1500:1, 1000:1 to 1500:1, 1100:1 to 1500:1, 1200:1 to 1500:1, 1300:1 to 1500:1, or 1400:1 to 1500:1.

The conduit may comprise at least one of a metal material, a polymer material, a ceramic material, or any combination thereof. In some embodiments, the conduit comprises a stainless steel.

As described herein, the conduit can include a coating.

The coating can comprise a vapor deposition coating. That is, for example, in some embodiments, a vapor deposition coating is a coating that is deposited, via a vapor deposition process, on the conduit. In some embodiments, for example, the coating comprises an atomic layer deposition (ALD) coating. It will be appreciated that the coating may be deposited on the conduit via other types of vapor deposition processes, including, for example and without limitation, at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

In some embodiments, the coating comprises a metal oxide of the formula: MO, where M is Ca, Mg, or Be. In some embodiments, the coating comprises a metal oxide of the formula M′O₂, where M′ is a metal having an oxidation state of 2+. In some embodiments, the coating comprises a metal oxide of the formula: Ln₂O₃, where Ln is a lanthanide (e.g., at least one of La, Sc, Y, or any combination thereof). In some embodiments, the coating comprises an aluminum oxide and a silicon oxide. In some embodiments, the aluminum oxide and the silicone oxide form a laminate film. In some embodiments, the coating comprises at least one of yttria (Y₂O₃), alumina (Al₂O₃), or any combination thereof. In some embodiments, the coating comprises any one or more of the forgoing in any combination.

The coating covers an inner surface of the conduit. In some embodiments, the inner surface of the conduit has a non-vapor-exposed surface portion and a vapor-exposed surface portion. In some embodiments, the non-vapor-exposed surface portion is a surface portion of the inner surface of the conduit that is not exposed to a precursor vapor when the coating is deposited via a vapor deposition process. In some embodiments, the vapor-exposed surface portion is a surface portion of the inner surface of the conduit that is exposed to the precursor vapor when the coating is deposited via a vapor deposition process. In some embodiments, the coating directly contacts the inner surface of the conduit. In some embodiments, the coating directly contacts the vapor-exposed surface portion of the inner surface of the conduit. In some embodiments, the coating does not cover the non-vapor-exposed surface portion of the inner surface of the conduit.

In some embodiments, the coating covers 90% to 99.9999% of the inner surface of the conduit, or any range or subrange between 90% and 99.9999%. In some embodiments, the coating covers 90% to 99.999%, 90% to 99.99%, 90% to 99.9%, 90% to 99%, 90% to 98%, 90% to 97%, 90% to 96%, 90% to 95%, 90% to 94%, 90% to 93%, 90% to 92%, 90% to 91%, 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999, 99.9% to 99.9999%, 99.99% to 99.9999%, or 99.999% to 99.9999% of the inner surface of the conduit.

In embodiments in which the conduit has a vapor exposed portion and a non-vapor exposed portion, the coating covers 90% to 99.9999% of the vapor-exposed surface portion inner surface of the conduit, or any range or subrange between 90% and 99.9999%. In some embodiments, the coating covers 90% to 99.999%, 90% to 99.99%, 90% to 99.9%, 90% to 99%, 90% to 98%, 90% to 97%, 90% to 96%, 90% to 95%, 90% to 94%, 90% to 93%, 90% to 92%, 90% to 91%, 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999, 99.9% to 99.9999%, 99.99% to 99.9999%, or 99.999% to 99.9999% of the vapor-exposed surface portion inner surface of the conduit.

An average thickness of the coating may be 5 nm to 250 nm, or any range or subrange between 5 nm and 250 nm. For example, in some embodiments, the average thickness of the coating is 5 nm to 250 nm, 5 nm to 240 nm, 5 nm to 230 nm, 5 nm to 220 nm, 5 nm to 210 nm, 5 nm to 200 nm, 5 nm to 190 nm, 5 nm to 180 nm, 5 nm to 170 nm, 5 nm to 160 nm, 5 nm to 150 nm, 5 nm to 140 nm, 5 nm to 130 nm, 5 nm to 120 nm, 5 nm to 120 nm, 5 nm to 110 nm, 5 nm to 100 nm, 5 nm to 90 nm, 5 nm to 80 nm, 5 nm to 70 nm, 5 nm to 60 nm, 5 nm to 50 nm, 5 nm to 40 nm, 5 nm to 30 nm, 5 nm to 20 nm, 5 nm to 10 nm, 10 nm to 250 nm, 20 nm to 250 nm, 30 nm to 250 nm, 40 nm to 250 nm, 50 nm to 250 nm, 60 nm to 250 nm, 70 nm to 250 nm, 80 nm to 250 nm, 90 nm to 250 nm, 100 nm to 250, 110 nm to 250 nm, 120 nm to 250 nm, 130 nm to 250 nm, 140 nm to 250 nm, 150 nm to 250 nm, 160 nm to 250 nm, 170 nm to 250 nm, 180 nm to 250 nm, 190 nm to 250 nm, 200 nm to 250, 210 nm to 250 nm, 220 nm to 250 nm, 230 nm to 250 nm, or 240 nm to 250 nm.

A thickness of the coating, between the inlet of the conduit and the outlet of the conduit, is within 1% of an average thickness of the coating. In some embodiments, a thickness of the coating, between the inlet of the conduit and the outlet of the conduit is within 0.01% to 1% of an average thickness of the coating, or any range or subrange between 0.01% and 1%. For example, in some embodiments, a thickness of the coating, between the inlet of the conduit and the outlet of the conduit is within 0.01% to 1%, 0.1% to 1%, 0.2% to 1%, 0.3% to 1%, 0.4% to 1%, 0.5% to 1%, 0.6% to 1%, 0.7% to 1%, 0.8% to 1%, 0.9% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, or 0.01% to 0.1% of an average thickness of the coating.

In some embodiments, the coated conduit has a bend angle. For example, in some embodiments, the coated conduit has at least one bend angle of 1° to 170°, 1° to 160°, 1° to 150°, 1° to 140°, 1° to 130°, 1° to 120°, 1° to 110°, 1° to 100°, 1° to 90°, 1° to 80°, 1° to 70°, 1° to 60°, 1° to 50°, 1° to 40°, 1° to 30°, 1° to 20°, 1° to 10°, 10° to 180°, 20° to 180°, 30° to 180°, 40° to 180°, 50° to 180°, 60° to 180°, 70° to 180°, 80° to 180°, 90° to 180°, 100° to 180°, 110° to 180°, 120° to 180°, 130° to 180°, 140° to 180°, 150° to 180°, 160° to 180°, or 170° to 180°. In other embodiments, the coated conduit can be coiled.

In some embodiments, the coating is pinhole free.

In some embodiments, when the coated component is a coated conduit, the coated component is configured for a gas flow, throughout a length of the conduit, from an inlet of the conduit to an outlet of the conduit. In some embodiments, when the coated component is a coated conduit, the coated component is configured for vapor flow, throughout a length of the conduit, from an inlet of the conduit to an outlet of the conduit. In some embodiments, the coated component is configured for flowing a precursor, such as, for example and without limitation, a precursor vapor. The precursor may exist in a solid or liquid phase and may be vaporized (e.g., via heating) to obtain a vaporized precursor.

In some embodiments, the precursor comprises at least one of elemental metal, metal halides, metal oxyhalides, metalorganic complexes, or any combination thereof. For example, in some embodiments, the precursor material comprises, consists of, or consists essentially of, or is selected from the group consisting of, at least one of elemental boron, copper, phosphorus, decaborane, gallium halides, indium halides, antimony halides, arsenic halides, gallium halides, aluminum iodide, titanium iodide, MoO₂Cl₂, MoOCl₄, MoCl₅, WCl₅, WOCl₄, WCl₆, cyclopentadienylcycloheptatrienyltitanium (CpTiCht), cyclooctatetraenecyclopenta-dienyltitanium, biscyclopentadienyltitanium-diazide, In(CH₃)₂(hfac), dibromomethyl stibine, tungsten carbonyl, metalorganic β-diketonate complexes, metalorganic alkoxide complexes, metalorganic carboxylate complexes, metalorganic aryl complexes, metalorganic amido complexes, or any combination thereof.

In some embodiments, the precursor comprises at least one of any type of source material that can be liquefied either by heating or solubilization in a solvent including, for example and without limitation, at least one of decaborane, (B₁₀H1₄), pentaborane (B₅H₉), octadecaborane (B1₈H₂₂), boric acid (H₃BO₃), SbCl₃, SbCl₅, or any combination thereof. In some embodiments, the precursor comprises at least one of at least one of AsCl₃, AsBr₃, AsF₃, AsF₅, As₄O₆, As₂Se₃m As₂S₂, AS₂S₃, As₂S₅, As₂Te₃, B₄H₁₁, B₄H₁₀, B₃H₆N₃, BBr₃, BCl₃, BF₃.O(C₂H₅)₂, BF₃.HOCH₃, B₂H₆, GeBr₄, GeCl₄, GeF₄, GeH₄, SiHCl₃, SiCl₄, SiH₃Cl, Br₂, BrF₅, COCl₂, COF₂, Ni(CO)₄, C₈H₂₄O₄Si₄, PH₃, POCl₃, PCl₅, PF₃, PFS, SbH₃, SF₄, Si(OC₂H₅)₄, C₄H₁₆Si₄O₄, Si(CH₃)₄, SiH(CH₃)₃, TiCl₄, WOF₄, TaBr₅, TaCl₅, TaF₅, Sb(C₂H₅)₃, Sb(CH₃)₃, In(CH₃)₃, PBr₅, PBr₃, RuF₅, or any combination thereof.

In some embodiments, when a gas or vapor is flowed through a coated conduit, as described herein, the gas or vapor collected at an outlet of the conduit exhibits a reduction in the amount of a metal impurity detected in the gas or vapor compared to an amount of the metal impurity detected in a gas or vapor when the gas or vapor is flowed through an uncoated conduit. To determine an amount of a metal impurity in a gas or vapor that is flowed through a coated or non-coated conduit, the gas or vapor is captured at the outlet using an impinger or other trap and the fluid is analyzed using inductively coupled plasma mass spectrometry (ICPS).

In some embodiments, when a gas or vapor is flowed through a coated conduit, the gas or vapor collected at an outlet exhibits at least a 50% reduction, at least a 60% reduction, at least a 70% reduction, at least an 80% reduction, at least a 90% reduction, or at least a 100% reduction in the amount of a metal impurity detected in the gas or vapor compared to an amount of the metal impurity detected in the gas or vapor when the gas or vapor is flowed through an uncoated conduit.

In some embodiments, when an ozone gas stream is flowed through a coated conduit, as described herein, ozone gas collected at an outlet of the conduit exhibits a reduction in the amount of chromium impurities detected in the ozone gas stream compared to an amount of chromium impurities detected in an ozone gas stream flowed through a bare stainless steel conduit. In some embodiments, when an ozone gas stream is flowed through a coated conduit, as described herein, the ozone gas collected at an outlet exhibits at least a 50% reduction, at least a 60% reduction, at least a 70% reduction, at least an 80% reduction, at least a 90% reduction, at least a 95% reduction, or at least a 100% reduction in the amount of chromium impurities detected in the ozone gas stream compared to an amount of chromium impurities detected in an ozone gas stream when an ozone gas stream is flowed through an uncoated conduit.

Additionally, or alternatively, when an ozone gas stream is flowed through a coated conduit, as described herein, ozone gas collected at an outlet of the conduit exhibits a reduction in the amount of manganese impurities detected in the ozone gas stream compared to an amount of manganese impurities detected in an ozone gas stream flowed through a bare stainless steel conduit. In some embodiments, when an ozone gas stream is flowed through a coated conduit, as described herein, the ozone gas collected at an outlet exhibits at least a 50% reduction, at least a 60% reduction, at least a 70% reduction, at least an 80% reduction, at least a 90% reduction, at least a 95% reduction, or at least a 100% reduction in the amount of manganese impurities detected in the ozone gas stream compared to an amount of manganese impurities detected in an ozone gas stream when an ozone gas stream is flowed through an uncoated conduit.

In some embodiments, the coated conduit shows a reduction in metal impurities present in MoO2Cl2 g vapor that is flowed through the coated conduit compared to MoO2Cl2 vapor flowed through a bare stainless steel conduit. In some embodiments, when MoO2Cl2 g vapor is flowed through a coated conduit, as described herein, MoO2Cl2 g vapor collected at an outlet of the conduit exhibits a reduction in the amount of iron impurities detected in the MoO2Cl2 g vapor compared to an amount of iron impurities detected in MoO2Cl2 g vapor flowed through a bare stainless steel conduit. In some embodiments, when MoO2Cl2 g vapor is flowed through a coated conduit, as described herein, the ozone gas collected at an outlet exhibits at least a 50% reduction, at least a 60% reduction, at least a 70% reduction, at least an 80% reduction, at least a 90% reduction, at least a 95% reduction, or at least a 100% reduction in the amount of iron impurities detected in the MoO2Cl2 g vapor compared to an amount of iron impurities detected in MoO2Cl2 g vapor when MoO2Cl2 g vapor is flowed through an uncoated conduit.

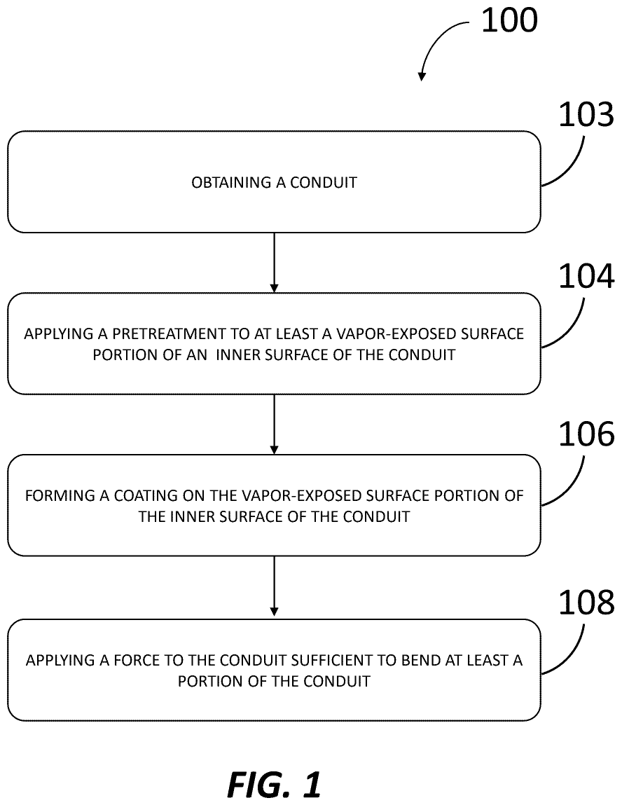

FIG. 1 is a schematic diagram of a flowchart of a method 100, according to some embodiments. As shown in FIG. 1, in some embodiments, the method 100 comprises one or more of the following steps: obtaining 103 a conduit; applying 104 a pretreatment to at least a vapor-exposed surface portion of an inner surface of the conduit; forming 106 a coating on the vapor-exposed surface portion of the inner surface of the conduit; and applying 108 a force to the conduit sufficient to bend at least a portion of the conduit.

At step 103, in some embodiments, the method 100 comprises obtaining a conduit.

The conduit may comprise an inlet, an outlet, an inner surface, and an outer surface. It will be appreciated that any one or more of the coated conduits disclosed herein may be used, without departing from the scope of this disclosure. For example, in some embodiments, the conduit has an atomic layer deposition (ALD) coating covering an inner surface of the conduit. In some embodiments, the conduit does not have an atomic layer deposition (ALD) coating covering an outer surface of the conduit.

At step 104, in some embodiments, the method 100 comprises applying a pretreatment to at least a vapor-exposed surface portion of the inner surface of the conduit.

In some embodiments, the applying comprises removing substances from an inner surface of the conduit. In some embodiments, the applying comprises modifying the inner surface of the conduit. In some embodiments, the applying comprises contacting the inner surface of the conduit with a solution. In some embodiments, the applying comprises contacting the inner surface of the conduit with an article (e.g., an abrasive, a mesh, a pad, etc.) for mechanically removing substances from the inner surface of the conduit. In some embodiments, the applying comprises physically removing at least one substance from the inner surface of the conduit. In some embodiments, the applying comprises chemically removing at least one substance from the inner surface of the conduit. In some embodiments, the pretreatment is sufficient to at least minimize formation of defects on or in the coating. In some embodiments, the pretreatment is sufficient to at least minimize formation of areas without coating (e.g., discontinuous coating areas). In some embodiments, the pretreatment is sufficient to permit bending or manipulating of the coated conduit, without cracking and/or without delamination.

The inner surface of the conduit may have a vapor-exposed surface portion and a non-vapor exposed surface portion. In some embodiments, the vapor-exposed surface portion is a surface portion of the inner surface of the conduit that is to be exposed to a vapor during a vapor deposition process. In some embodiments, the non-vapor-exposed surface portion is a surface portion of the inner surface of the conduit that is not to be exposed to a vapor during a vapor deposition process. In some embodiments, the non-vapor-exposed surface portion may be covered or otherwise masked by a substance such that the non-vapor-exposed surface portion does not directly contact a vapor during a vapor deposition process. In some embodiments, the vapor-exposed surface portion may not be an uncovered surface portion such that the vapor-exposed surface portion directly contacts a vapor during a vapor deposition process.

The non-vapor-exposed surface portion of the inner surface of the conduit may comprise less than 20% of a surface area of an inner surface of the conduit. In some embodiments, the non-vapor exposed surface portion of the inner surface of the conduit comprises 1% to 20% of the surface area of the inner surface of the conduit, or any range or subrange between 1% and 20%. For example, in some embodiments, the non-vapor exposed surface portion of the inner surface of the conduit comprises 1% to 15%, 1% to 10%, 1% to 5%, 5% to 20%, 10% to 20%, or 15% to 20% of the surface area of the inner surface of the conduit. In some embodiments, the conduit does not comprise a non-vapor-exposed surface portion of the inner surface.

In some embodiments, a balance of the surface area of the inner surface of the conduit is the vapor-exposed surface portion of the inner surface of the conduit. For example, in some embodiments, the vapor-exposed surface portion of the inner surface of the conduit comprises 80% to 99% of the surface area of the inner surface of the conduit, or any range or subrange between 80% and 99%. In some embodiments, the vapor-exposed surface portion of the inner surface of the conduit comprises 80% to 99%, 85% to 99%, 90% to 99%, 95% to 99%, 80% to 95%, 80% to 90%, or 80% to 85% of the surface area of the inner surface of the conduit. In some embodiments, the vapor-exposed surface portion is an entire inner surface of the conduit.

At step 106, in some embodiments, the method 100 comprises forming a coating on the vapor-exposed portion of the inner surface of the conduit. In some embodiments, the coating comprises at least one of alumina, yttria, or a combination thereof. In other embodiments, the coating can include other coating materials as described herein.

In some embodiments, the forming comprises a vapor deposition process. For example, in some embodiments, the forming comprises forming a coating via at least one of a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof. In some embodiments, the forming comprises flowing a vapor precursor suitable for forming the desired coating through the conduit. In some embodiments, the forming comprises flowing a co-reactant precursor through the conduit. The vapor precursor and/or co-reactant precursor may comprise any one or more of the precursors disclosed herein, derivatives thereof, without departing from the scope of this disclosure.

In some embodiments, the forming comprises forming a coating covering all or at least a portion of the inner surface of the conduit. In some embodiments, the forming comprises forming a coating covering the vapor-exposed surface portion of the inner surface of the conduit. In some embodiments, the forming does not comprise forming a coating on an outer surface of the conduit. In some embodiments, the method does not comprise forming a coating on the outer surface of the conduit.

In some embodiments, the forming comprises forming a coating on an inner surface of a conduit having an aspect ratio of 2:1 to 1000:1. In some embodiments, an aspect ratio is a ratio of the length of the conduit to the width of a cross-section of the conduit is 2:1 to 1000:1, or any range or subrange between 2:1 and 1500:1. In some embodiments, the forming comprising forming a coating on an inner surface of a conduit, wherein a ratio of the length of the conduit to the width of the cross-section of the conduit is 2:1 to 1400:1, 2:1 to 1300:1, 2:1 to 1200:1, 2:1 to 1100:1, 2:1 to 1000:1, 2:1 to 900:1, 2:1 to 800:1, 2:1 to 700:1, 2:1 to 600:1, 2:1 to 500:1, 2:1 to 400:1, 2:1 to 300:1, 2:1 to 200:1, 2:1 to 100:1, 2:1 to 50:1, 100:1 to 1500:1, 200:1 to 1500:1, 300:1 to 1500:1, 400:1 to 1500:1, 500:1 to 1500:1, 600:1 to 1500:1, 700:1 to 1500:1, 800:1 to 1500:1, 900:1 to 1500:1, 1000:1 to 1500:1, 1100:1 to 1500:1, 1200:1 to 1500:1, 1300:1 to 1500:1, or 1400:1 to 1500:1.

In some embodiments, the forming comprises forming a coating having an average thickness of 5 nm to 250 nm. In some embodiments, the forming comprises forming a coating having an average thickness of 5 nm to 250 nm, 5 nm to 240 nm, 5 nm to 230 nm, 5 nm to 220 nm, 5 nm to 210 nm, 5 nm to 200 nm, 5 nm to 190 nm, 5 nm to 180 nm, 5 nm to 170 nm, 5 nm to 160 nm, 5 nm to 150 nm, 5 nm to 140 nm, 5 nm to 130 nm, 5 nm to 120 nm, 5 nm to 120 nm, 5 nm to 110 nm, 5 nm to 100 nm, 5 nm to 90 nm, 5 nm to 80 nm, 5 nm to 70 nm, 5 nm to 60 nm, 5 nm to 50 nm, 5 nm to 40 nm, 5 nm to 30 nm, 5 nm to 20 nm, 5 nm to 10 nm, 10 nm to 250 nm, 20 nm to 250 nm, 30 nm to 250 nm, 40 nm to 250 nm, 50 nm to 250 nm, 60 nm to 250 nm, 70 nm to 250 nm, 80 nm to 250 nm, 90 nm to 250 nm, 100 nm to 250, 110 nm to 250 nm, 120 nm to 250 nm, 130 nm to 250 nm, 140 nm to 250 nm, 150 nm to 250 nm, 160 nm to 250 nm, 170 nm to 250 nm, 180 nm to 250 nm, 190 nm to 250 nm, 200 nm to 250, 210 nm to 250 nm, 220 nm to 250 nm, 230 nm to 250 nm, or 240 nm to 250 nm.

In some embodiments, the forming comprises forming a coating having a thickness that is within 1% of an average thickness of the coating. In some embodiments, the forming comprises forming a coating having a thickness that is within 0.01% to 1%, 0.1% to 1%, 0.2% to 1%, 0.3% to 1%, 0.4% to 1%, 0.5% to 1%, 0.6% to 1%, 0.7% to 1%, 0.8% to 1%, 0.9% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, or 0.01% to 0.1% of an average thickness of the coating.

In some embodiments, the forming comprises forming a coating covering 90% to 99.9999% of the inner surface of the conduit. In some embodiments, the forming comprises forming a coating covering 90% to 99.999%, 90% to 99.99%, 90% to 99.9%, 90% to 99%, 90% to 98%, 90% to 97%, 90% to 96%, 90% to 95%, 90% to 94%, 90% to 93%, 90% to 92%, 90% to 91%, 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999, 99.9% to 99.9999%, 99.99% to 99.9999%, or 99.999% to 99.9999% of the inner surface of the conduit.

In some embodiments, the forming comprises forming a coating covering 80% to 99.9999% of the vapor-exposed surface portion inner surface of the conduit. In some embodiments, the forming comprises forming a coating covering 90% to 99.999%, 90% to 99.99%, 90% to 99.9%, 90% to 99%, 90% to 98%, 90% to 97%, 90% to 96%, 90% to 95%, 90% to 94%, 90% to 93%, 90% to 92%, 90% to 91%, 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999, 99.9% to 99.9999%, 99.99% to 99.9999%, or 99.999% to 99.9999% of the vapor-exposed surface portion inner surface of the conduit.

At step 108, in some embodiments, the method 100 comprises applying a force to the conduit sufficient to bend at least a portion of the conduit.

In some embodiments, the applying a force is performed after forming the coating. The manner in which the conduit (i.e., coated conduit) is bent is not particularly limited and can be performed using tools and/or machines, among other things. In some embodiments, applying the force does not result in cracking of the coating. In some embodiments, applying the force does not result in cracking of the coating based on a visual inspection before and after the force is applied. In some embodiments, applying the force results in less cracks in the coating as compared to a force applied to a control conduit comprising a coating (e.g., a non-ALD coating, or other non-vapor deposition coating). In some embodiments, applying the force does not result in delamination of the coating. For example, in some embodiments, applying the force does not result in delamination of the coating based on a visual inspection before and after the force is applied. In some embodiments, applying the force results in a lesser extent of delamination of the coating as compared to a force applied to a control conduit comprising a coating, wherein the coating is not an ALD coating, or other vapor deposition coating.

In some embodiments, the force applied is sufficient to result in a bend angle between 1° and 180°, or any range or subrange between 1° and 180°. For example, in some embodiments, the force applied is sufficient to result in a bend angle of 1° to 170°, 1° to 160°, 1° to 150°, 1° to 140°, 1° to 130°, 1° to 120°, 1° to 110°, 1° to 100°, 1° to 90°, 1° to 80°, 1° to 70°, 1° to 60°, 1° to 50°, 1° to 40°, 1° to 30°, 1° to 20°, 1° to 10°, 10° to 180°, 20° to 180°, 30° to 180°, 40° to 180°, 50° to 180°, 60° to 180°, 70° to 180°, 80° to 180°, 90° to 180°, 100° to 180°, 110° to 180°, 120° to 180°, 130° to 180°, 140° to 180°, 150° to 180°, 160° to 180°, or 170° to 180°.

In other embodiments, the conduit is coiled prior to coating and the step pf forming the coating comprises flowing a vapor precursor suitable for forming the desired coating through the conduit. In some embodiments, the forming comprises flowing a co-reactant precursor through the conduit. The vapor precursor and/or co-reactant precursor may comprise any one or more of the precursors disclosed herein, derivatives thereof, without departing from the scope of this disclosure.

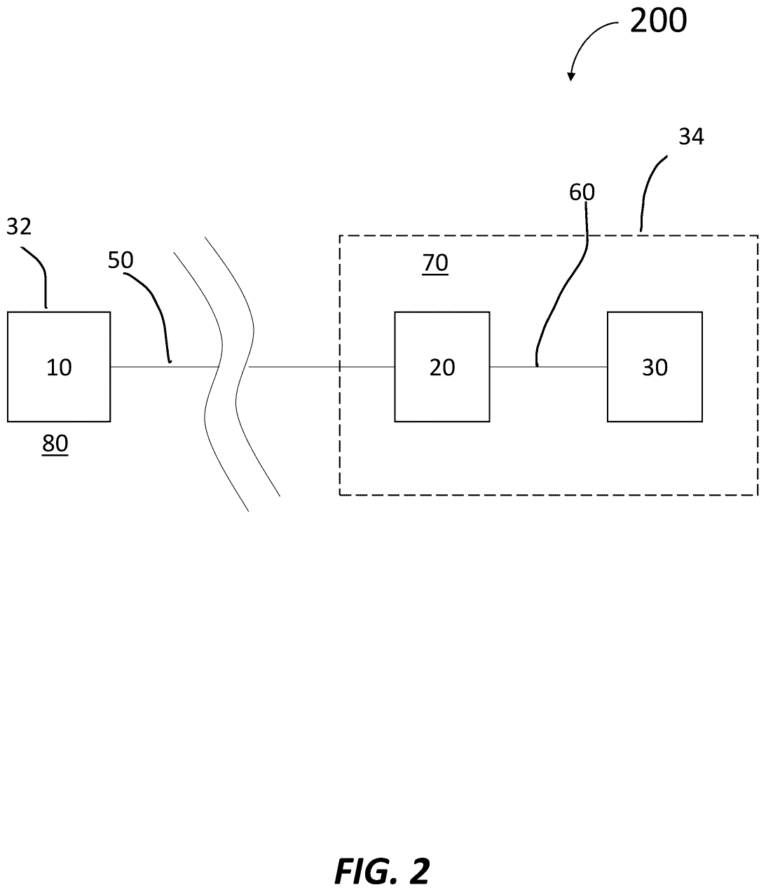

FIG. 2 is a schematic diagram of an exemplary system including a conduit. As shown in FIG. 2, the system 200 comprises at least one first container 10, at least one second container 20, and at least one semiconductor process tool 30. In some embodiments, the semiconductor process tool 30 is a deposition tool. In some embodiments, the at least one first container 10 is located in a first subsystem 32. In some embodiments, the at least one second container 20 is located in a second subsystem 34. In some embodiments, as shown, the system 200 can include a first conduit 50 connecting the at least one first container 10 to the at least one second container 20. The system 20 can include a second conduit 60 connecting the at least one second container 20 to the at least one semiconductor process tool 30. Each of the first and/or second conduits 50, 60 can be a coated conduit as described herein according to various embodiments. In some embodiments, the conduit fluidly connects at least one container of the first subsystem 32 to at least one container 20 or 30 of the second subsystem 34. It will be appreciated that the first conduit 50 and the second conduit 60 may independently comprise any one or more of the conduits disclosed herein, without departing from the scope of this disclosure. For brevity, the various embodiments of the conduits, as disclosed herein, are not repeated here.

The at least one first container 10 and/or the at least one second container 20 may be located in different locations of a facility, such as, for example and without limitation, in different locations of a semiconductor manufacturing facility, among others. As shown in FIG. 2, for example, in some embodiments, the at least one second container 20 and the at least one semiconductor process tool 30 are located in a fabrication area 70 (e.g., “fab”). In some embodiments, the at least one first container 10 is located in a non-fabrication area 80 (e.g., located in an area outside the fabrication area, such as, a sub-fabrication area or “subfab”). In some embodiments, the non-fabrication area 80 is an area located beneath the fabrication area 70. In other embodiments, the at least one second container is located in a non-fabrication area, wherein the at least one second container is closer to the semiconductor process tool 30 than the at least one first container 10.

According to some embodiments, the at least one first container 10 can contain a precursor. In some embodiments, the at least one first container 10 is configured to vaporize the precursor to obtain a vaporized precursor. In some embodiments, the at least one first container 10 is configured to vaporize a precursor for vapor deposition on a semiconductor substrate. In these embodiments, semiconductor process tool 30 is a deposition tool. In some embodiments, the at least one first container 10 is configured to deliver the vaporized precursor to the first conduit 50 for transport to the at least one second container 20. In some embodiments, the at least one second container 20 is configured to receive the vaporized precursor from the first conduit 50 and the at least one first container 10. In some embodiments, the vapor is recondensed in the second container 20 while the vapor is being received through the first conduit 50. In some embodiments, the at least one second container 20 is configured to store the precursor in solid phase or gas/vapor phase. In some embodiments, the at least one second container 20 is configured to vaporize the precursor to obtain a vaporized precursor. In some embodiments, the at least one second container 20 is configured to deliver the vaporized precursor to the second conduit 60 for transport to the at least one semiconductor process tool 30.

The first conduit 50 may be configured to deliver the vaporized precursor, at a first temperature, from the at least one first container to the at least one second container. The second conduit 60 may be configured to deliver the vaporized precursor, at a second temperature, from the at least one second container 20 to the at least one semiconductor process tool 30 (e.g. deposition tool). In some embodiments, the first temperature is less than the second temperature. In some embodiments, the first temperature is 1% to 99%, 5% to 99%, 10% to 99%, 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, 95% to 99%, 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, or 5% to 10% less than the second temperature.

The first temperature may be a temperature of 50° C. to 200° C., or any range or subrange between 50° C. and 200° C. In some embodiments, the first temperature is a temperature of 50° C. to 190° C., 50° C. to 180° C., 50° C. to 170° C., 50° C. to 160° C., 50° C. to 150° C., 50° C. to 140° C., 50° C. to 130° C., 50° C. to 120° C., 50° C. to 110° C., 50° C. to 100° C., 50° C. to 90° C., 50° C. to 80° C., 50° C. to 70° C., or 50° C. to 60° C. In some embodiments, the first temperature is a temperature of 60° C. to 200° C., 70° C. to 200° C., 80° C. to 200° C., 90° C. to 200° C., 100° C. to 200° C., 110° C. to 200° C., 120° C. to 200° C., 130° C. to 200° C., 140° C. to 200° C., 150° C. to 200° C., 160° C. to 200° C., 170° C. to 200° C., 180° C. to 200° C., or 190° C. to 200° C.

The second temperature may be a temperature of 100° C. to 300° C., or any range or subrange between 100° C. and 300° C. In some embodiments, the second temperature is a temperature of 100° C. to 290° C., 100° C. to 280° C., 100° C. to 270° C., 100° C. to 260° C., 100° C. to 250° C., 100° C. to 240° C., 100° C. to 230° C., 100° C. to 220° C., 100° C. to 210° C., 100° C. to 200° C., 100° C. to 190° C., 100° C. to 180° C., 100° C. to 170° C., 100° C. to 160° C., 100° C. to 150° C., 100° C. to 140° C., 100° C. to 130° C., 100° C. to 120° C., 100° C. to 110° C., 110° C. to 300° C., 120° C. to 300° C., 130° C. to 300° C., 140° C. to 300° C., 150° C. to 300° C., 160° C. to 300° C., 170° C. to 300° C., 180° C. to 300° C., 190° C. to 300° C., 200° C. to 300° C., 210° C. to 300° C., 220° C. to 300° C., 230° C. to 300° C., 240° C. to 300° C., 250° C. to 300° C., 260° C. to 300° C., 270° C. to 300° C., 280° C. to 300° C., or 290° C. to 300° C.

The first conduit 50 may be configured to deliver the vaporized precursor, at a first pressure, from the at least one first container 10 to the at least one second container 20. The second conduit 60 may be configured to deliver the vaporized precursor, at a second pressure, from the at least one second container 20 to the at least one semiconductor tool 30 (e.g., deposition tool). In some embodiments, the first pressure is less than the second pressure. In some embodiments, the first pressure is 1% to 99%, 5% to 99%, 10% to 99%, 15% to 99%, 20% to 99%, 25% to 99%, 30% to 99%, 35% to 99%, 40% to 99%, 45% to 99%, 50% to 99%, 55% to 99%, 60% to 99%, 65% to 99%, 70% to 99%, 75% to 99%, 80% to 99%, 85% to 99%, 90% to 99%, 95% to 99%, 5% to 95%, 5% to 90%, 5% to 85%, 5% to 80%, 5% to 75%, 5% to 70%, 5% to 65%, 5% to 60%, 5% to 55%, 5% to 50%, 5% to 45%, 5% to 40%, 5% to 35%, 5% to 30%, 5% to 25%, 5% to 20%, 5% to 15%, or 5% to 10% less than the second pressure.

The first pressure may be a pressure of 0.1 Torr to 300 Torr, or any range or subrange between 0.1 Torr and 300 Torr. In some embodiments, the first pressure is a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 10 Torr to 50 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, 250 Torr to 300 Torr.

The second pressure may be a pressure of 0.1 Torr to 300 Torr, or any range or subrange between 0.1 Torr and 300 Torr. In some embodiments, the second pressure is a pressure of 0.1 Torr to 290 Torr, 0.1 Torr to 280 Torr, 0.1 Torr to 270 Torr, 0.1 Torr to 260 Torr, 0.1 Torr to 250 Torr, 0.1 Torr to 240 Torr, 0.1 Torr to 230 Torr, 0.1 Torr to 220 Torr, 0.1 Torr to 210 Torr, 0.1 Torr to 200 Torr, 0.1 Torr to 190 Torr, 0.1 Torr to 180 Torr, 0.1 Torr to 170 Torr, 0.1 Torr to 160 Torr, 0.1 Torr to 150 Torr, 0.1 Torr to 140 Torr, 0.1 Torr to 130 Torr, 0.1 Torr to 120 Torr, 0.1 Torr to 110 Torr, 0.1 Torr to 100 Torr, 0.1 Torr to 90 Torr, 0.1 Torr to 80 Torr, 0.1 Torr to 70 Torr, 0.1 Torr to 60 Torr, 0.1 Torr to 50 Torr, 0.1 Torr to 40 Torr, 0.1 Torr to 30 Torr, 0.1 Torr to 20 Torr, 0.1 Torr to 10 Torr, 0.1 Torr to 9 Torr, 0.1 Torr to 8 Torr, 0.1 Torr to 7 Torr, 0.1 Torr to 6 Torr, 0.1 Torr to 5 Torr, 0.1 Torr to 4 Torr, 0.1 Torr to 3 Torr, 0.1 Torr to 2 Torr, 0.1 Torr to 1 Torr, 1 Torr to 300 Torr, 10 Torr to 300 Torr, 20 Torr to 300 Torr, 30 Torr to 300 Torr, 40 Torr to 300 Torr, 50 Torr to 300 Torr, 60 Torr to 300 Torr, 70 Torr to 300 Torr, 80 Torr to 300 Torr, or 90 Torr to 300 Torr, 100 Torr to 300 Torr, 150 Torr to 300 Torr, 200 Torr to 300 Torr, or 250 Torr to 300 Torr.

The first conduit 50 may have a length that is greater than a length of the second conduit 60. For example, in some embodiments, the first conduit 50 has a length that is 1.1 times to 100 times a length of the second conduit 20. In some embodiments, the first conduit 10 has a length that is at least 1.1 times, at least 1.2 times, at least 1.3 times, at least 1.4 times, at least 1.5 times, at least 1.6 times, at least 1.7 times, at least 1.8 times, at least 1.9 times, at least 2 times, at least 2.1 times, at least 2.2 times, at least 2.3 times, at least 2.4 times, at least 2.5 times, at least 2.6 times, at least 2.7 times, at least 2.8 times, at least 2.9 times, at least 3 times, at least 3.1 times, at least 3.2 times, at least 3.3 times, at least 3.4 times, at least 3.5 times, at least 3.6 times, at least 3.7 times, at least 3.8 times, at least 3.9 times, at least 4 times, at least 4.1 times, at least 4.2 times, at least 4.3 times, at least 4.4 times, at least 4.5 times, at least 4.6 times, at least 4.7 times, at least 4.8 times, at least 4.9 times, at least 5 times, at least 5.5 times, at least 6 times, at least 6.5 times, at least 7 times, at least 7.5 times, at least 8 times, at least 8.5 times, at least 9 times, at least 9.5 times, at least 10 times, at least 20 times, at least 50 times, at least 70 times, up to 100 times a length of the second conduit 60.

The flowrate through the first conduit 50 may range from 50 sccm to 1200 sccm, or any range or subrange between 50 sccm and 1200 sccm. For example, in some embodiments, the flowrate through the first conduit 50 is 50 sccm to 1100 sccm, 50 sccm to 1000 sccm, 50 sccm to 900 sccm, 50 sccm to 800 sccm, 50 sccm to 700 sccm, 50 sccm to 600 sccm, 50 sccm to 500 sccm, 50 sccm to 400 sccm, 50 sccm to 300 sccm, 50 sccm to 200 sccm, 50 sccm to 100 sccm, 100 sccm to 1200 sccm, 200 sccm to 1200 sccm, 300 sccm to 1200 sccm, 400 sccm to 1200 sccm, 500 sccm to 1200 sccm, 600 sccm to 1200 sccm, 700 sccm to 1200 sccm, 800 sccm to 1200 sccm, 900 sccm to 1200 sccm, 1000 sccm to 1200 sccm, or 1100 sccm to 1200 sccm.

The flowrate through the second conduit 60 may range from 50 sccm to 1200 sccm, or any range or subrange between 50 sccm and 1200 sccm. For example, in some embodiments, the flowrate through the second conduit 60 is 50 sccm to 1100 sccm, 50 sccm to 1000 sccm, 50 sccm to 900 sccm, 50 sccm to 800 sccm, 50 sccm to 700 sccm, 50 sccm to 600 sccm, 50 sccm to 500 sccm, 50 sccm to 400 sccm, 50 sccm to 300 sccm, 50 sccm to 200 sccm, 50 sccm to 100 sccm, 100 sccm to 1200 sccm, 200 sccm to 1200 sccm, 300 sccm to 1200 sccm, 400 sccm to 1200 sccm, 500 sccm to 1200 sccm, 600 sccm to 1200 sccm, 700 sccm to 1200 sccm, 800 sccm to 1200 sccm, 900 sccm to 1200 sccm, 1000 sccm to 1200 sccm, or 1100 sccm to 1200 sccm.

In some embodiments, the system 200 does not comprise a carrier gas source. In some embodiments, the system 200 is configured to transport the vaporized precursor by drawing the vaporized precursor through the first conduit 50 and/or the second conduit 60. In some embodiments, the system 200 further comprises, for example, a vacuum or a pump sufficient for drawing the vaporized precursor through the first conduit 50 and/or the second conduit 60. In some embodiments, the system 200 further comprises at least one vacuum, wherein the at least one vacuum is connected to at least one of the first conduit, the second conduit, or any combination thereof, wherein the at least one vacuum is configured for drawing the vaporized precursor through at least one of the first conduit (e.g., from the at least one first container 10 to the at least one second container 20), the second conduit (e.g., from the at least one second container 20 to the at least one semiconductor process tool 30), or any combination thereof.

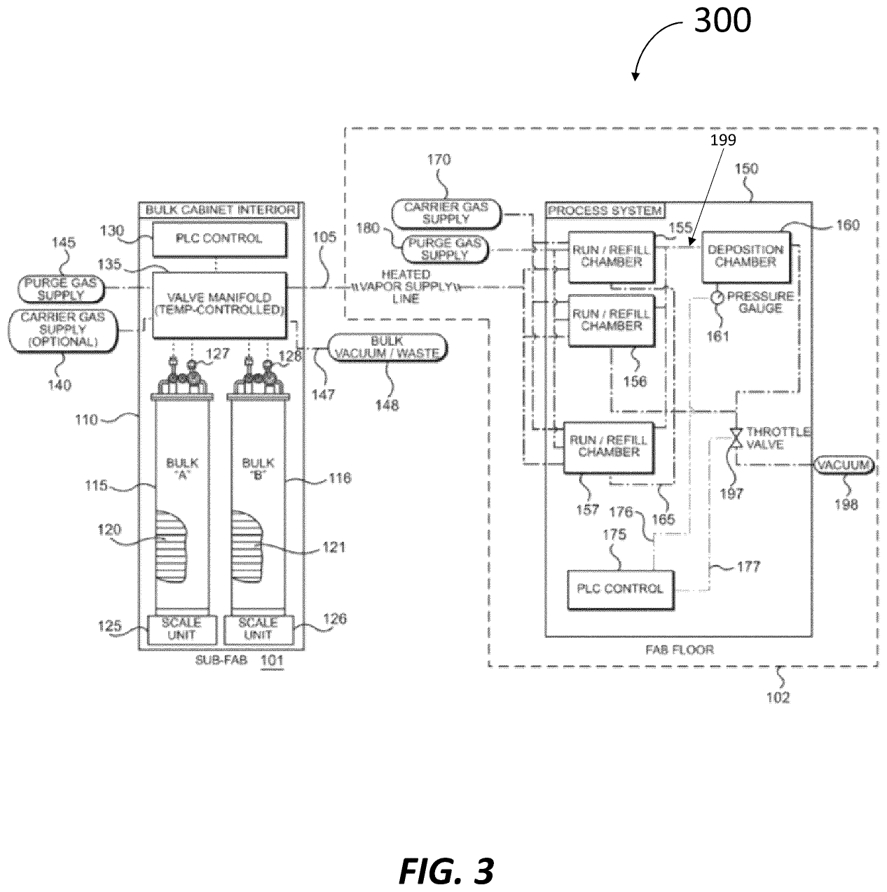

FIG. 3 is a schematic diagram of another exemplary system 300 including at least one conduit. The conduit can be a coated conduit as described herein according to the various embodiments. One portion of system 300 is located in a sub-fabrication area 101, hereinafter a sub-fab, while another portion is located in a fabrication area or floor 102 which is shown as enclosed by a dashed line, hereinafter, a fab. These portions are connected by a first conduit 105 which can be a heated vapor supply line. In some embodiments, first conduit 105 can be a coated conduit as described herein. A cabinet 110 can be located in the sub-fab but also could be located in a more remote location. The cabinet 110 houses a first container 115 and a second container 116. In some embodiments, containers 115 and 116 and their internal support structures are made of 316L stainless steel that is electro-polished. The 316L stainless steel is preferably coated with a thin film of a more resistant material for each specific chemistry, e.g., nickel, aluminum oxide, etc. In some embodiments, a metal alloy material can be employed. Inconel, Hastelloy C276, C22, Alloy 20, etc. are examples of such alloys. Also, different materials can be employed. For example, the containers can be made of 316L stainless steel, and the internal support structure can be made of a more resistant alloy or coated with a more resistant alloy. It will be appreciated that the cabinet 110 may comprise only a single container, or the cabinet 110 may comprise more than the first container 115 and the second container 116. For example, in some embodiments, the cabinet 110 may comprise a third container, a fourth container, a fifth container, a sixth container, a seventh container, an eighth container, a ninth container, a tenth container, or more than ten containers.

A precursor 120 is stored within container 115 in solid form, and a precursor 121 is stored within container 116 in solid form. Although different reference numerals are used, precursors 120 and 121 are typically the same material. In use, container 115, for example, is used until precursor 120 is depleted. Then, container 116 is used while container 115 is being replaced or refilled. After precursor 121 is depleted, container 115 is used while container 116 is being replaced or refilled. Accordingly, there is no downtime in this portion of the process. A first scale unit 125 and a second scale unit 126 are configured to weigh containers 115 and 116 to provide information regarding the amount of precursor 120 remaining within container 115 and the amount of precursor 121 remaining within container 116. Connection lines 127 and 128 allow for the precursor vapor to leave containers 115 and 116. Containers 115 and 116 can also employ additional monitoring features to monitor multiple temperature zones, vacuum level, mass delivery rate to first conduit 105, internal/external filtration, internal/external purification, impurity levels, etc. A programmable logic controller 130 controls a manifold 135 to regulate the transport of precursors 120 and 121 from containers 115 and 116 to the fab. Specifically, precursors 120 and 121 are heated in containers 115 and 116 to cause sublimation and the resulting vapor is transported to fab 102 via the conduit 105 (heated vapor supply line), optionally using a carrier gas supplied by a carrier gas supply 140. In some embodiments, no carrier gas is used as the transport is achieved by drawing vapor through the vapor supply line (e.g., under vacuum). The conditions of the first conduit or heated vapor supply line 105 can include any of the conditions disclosed herein and generally include a temperature and/or a pressure that is less than a temperature and/or a pressure of line 199. Conduit 105 is preferably also heated at or above the temperature of the precursor in containers 115 or 116 and monitored to measure precursor delivery rate. Precursors 120 and 121 are not typically transported through vapor supply line 105 at the same time. Instead, precursors 120 and 121 are preferably transported in an alternating fashion, as discussed above. A purge gas supplied by a purge gas supply 145 is used to purge the conduits through which precursors 120 and 121 pass (e.g., vapor supply line 105). The purge is preferably conducted with an automated cycle to remove potential chemical material from conduit 105 as it leaves containers 115 and 116 through connectors that are not separately labeled. Waste is removed from manifold 135 through a line 147 to a vacuum disposal unit 148. Line 147 can also be heated to limit condensation of waste product. As an alternative delivery method, containers 115 and 116 could be used in series or parallel with the proper manifolding. The manifolding would still allow a single container to provide vapor to the run/refill chambers while the other container is replaced. The option of series or parallel delivery would allow for more complete consumption of the precursor while not impacting the quantity of vapor available to the run/refill chambers. This alternative would reduce the amount of residual precursor in the container and would improve the cost of ownership.

As shown in FIG. 3, a process system 150 is located in fab 102. Process system 150 includes a plurality of run/refill chambers 155-157, which receive precursors 120 and 121 from conduit 105 (heated vapor supply line). In particular, precursors 120 and 121 enter run/refill chambers 155-157 as a vapor and are then solidified, or deposited, within run/refill chambers 155-157 as a solid by cooling run/refill chambers 155-157. For purposes of the present invention, the term “deposition”, and variants thereof, refers to the chemical vapor deposition (CVD) process whereby a precursor gas is chemically converted to a solid film rather than the more general act of putting an object in specific location. Precursors 120 and 121 are stored within run/refill chambers 155-157 in solid form. When needed, precursor 120, 121 is sublimated within one of run/refill chambers 155-157 by heating the corresponding run/refill chamber 155-157. The run refill chambers 155-157 are preferably heated and cooled rapidly between a run mode to the chamber and a refill mode to condense solids. Heating and cooling is preferably accomplished using one of several techniques including resistive heating, hot oil recirculation and radiant heating. Cooling can be done by chilled water, glycol, heat transfer fluid, a Peltier cooling device, Joule-Thompson cooling, etc. Precursor 120, 121 is then transported to a deposition chamber 160, which is preferably in close proximity to run/refill chambers 155-157 and includes a pressure gauge 161. Alternatively, precursor 120, 121 is transported to a second run/refill chamber 155-157. A vacuum conduit 165 connects chambers 155-157 to a vacuum. In the first scenario, the chosen one of precursors 120 and 121 is used to deposit a film on a substrate (not shown) located within deposition chamber 160. Additional co-reactant and inert gases are generally part of a CVD or ALD process. These are not shown but are delivered using conventional hardware including mass flow controllers (MFCs) and pressure controllers (PCs). In an atomic layer deposition (ALD) process, the delivery of the co-reactant gas is separated in time from the delivery of the precursor vapor. An optional carrier gas supply 170 can be used to transport precursors 120 and 121 within process system 150, while a programmable logic controller 175 controls process system 150. More specifically, controller 175 is connected through control lines 176 and 177 to gauge 161 and control valve 197 and is able to measure and control pressure in chamber 160 by opening valve 197, which leads to vacuum 198. A purge gas supplied by a purge gas supply 180 is used to purge run/refill chambers 155-157.

It will be appreciated that, although the deposition chamber 160 is in fluid communication with three run/refill chambers (i.e., run/refill chambers 155-157), the system 300 may comprise other configurations and quantities of run/refill chambers and deposition chambers. For example, in some embodiments, the system 300 comprises one or more of the following: a first run/refill chamber and a second run/refill chamber in fluid communication with a first deposition chamber; a third run/refill chamber and a fourth run/refill chamber in fluid communication with a second deposition chamber; a fifth run/refill chamber and a sixth run/refill chamber in fluid communication with a third deposition chamber; and so on. In some embodiments, the deposition chamber is in fluid communication with only a single run/refill chamber or more than two run/refill chambers (e.g., three run/refill chambers to ten or more run/refill chambers). In some embodiments, the system 300 comprises more than three deposition chambers (e.g., four deposition chambers to ten or more deposition chambers).

In some embodiments, each of run/refill chambers 155-157 is sized to hold an amount of precursor 120 or 121 sufficient for one deposition cycle but not two deposition cycles. In other embodiments, each of run/refill chambers 155-157 is sized to hold an amount of precursor 120 or 121 sufficient for a plurality of deposition cycles. The term “deposition cycle” refers to the steps by which a single layer of a film is deposited on a substrate. Although run/refill chambers 155-157 are labeled with different reference numerals, run/refill chambers 155-157 can be identical to one another.

The term “run/refill” means “run and/or refill”. A chamber (e.g., chamber 155) is being refilled when it is at its lower temperature setting and vapor is entering via vapor supply line 105 and condensing on the high surface area interior. Then, the chamber is running when it is at its higher temperature setting and the solid that had condensed during the refill part of the cycle is evaporated and the vapor is delivered to the deposition chamber via a line 199. The conditions of the line 199 (e.g., second conduit) can include any of the conditions disclosed herein and generally include a temperature and/or a pressure that is greater than a temperature and/or a pressure of conduit 105. The term “run/refill chamber” indicates that the chamber acts as both run and refill chambers. The run/refill chamber can incorporate filtration, purification, pressure/vacuum monitoring and delivery rate or solids film sensing. The run/refill chamber is preferably designed to be cycled for every wafer, or one “refill” of the run/refill chamber is designed to provide vapor for two or more wafers before getting “refilled” again.

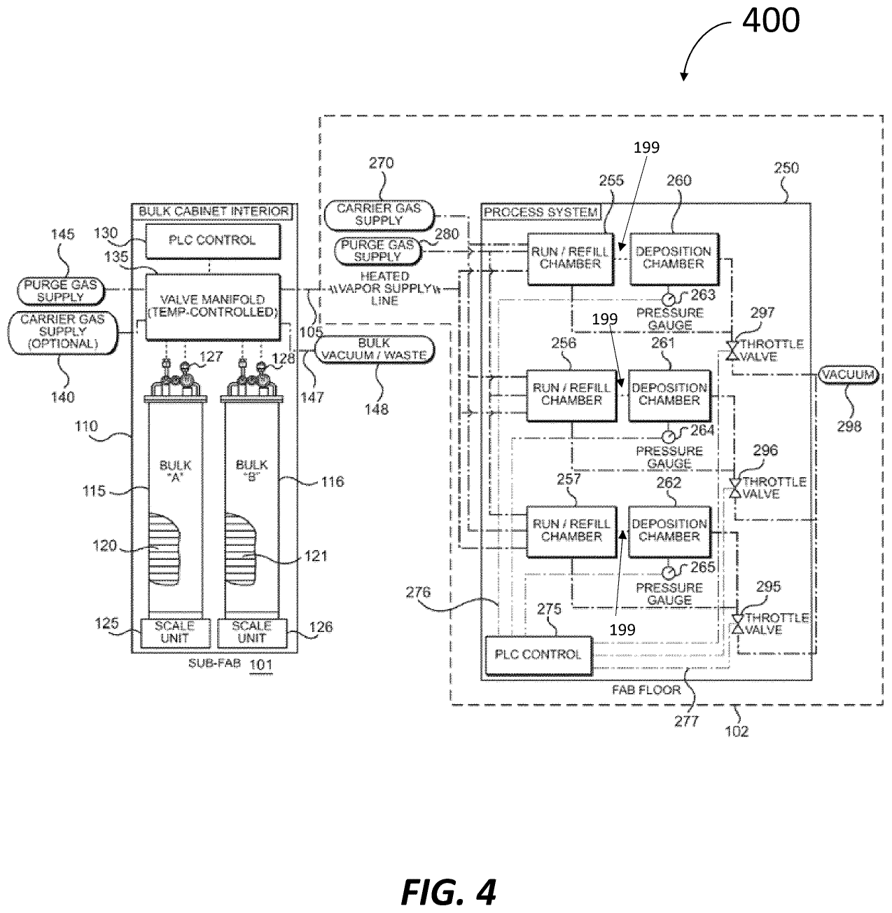

FIG. 4 is a schematic diagram of a system 400, according to some embodiments. System 400 generally functions in the same manner as system 300 except that system 400 has one run/refill chamber per deposition chamber. Specifically, a process system 250 includes a plurality of run/refill chambers 255-257, which receive precursors 120 and 121 from conduit 105 which can be a heated vapor supply line. In some embodiments, conduit 105 is a coated conduit as described herein. The conditions of the first conduit 105 can include any of the conditions disclosed herein and generally include a temperature and/or a pressure that is less than a temperature and/or a pressure of line 199. Precursors 120 and 121 enter run/refill chambers 255-257 as a vapor and are then deposited within run/refill chambers 255-257 as a solid by cooling run/refill chambers 255-257. When needed, precursor 120 or 121 is sublimated within one of run/refill chambers 255-257 by heating that run/refill chamber 255-257. Precursor 120 or 121 is then transported to a corresponding one of a plurality of deposition chambers 260-262 via lines 199. Precursor 120 or 121 is used to deposit a film on a substrate (not shown) located within the corresponding deposition chamber 260-262. An optional carrier gas supply 270 can be used to transport precursors 120 and 121 within process system 250, while a controller 275 controls process system 250. Controller 275 is connected to gauges 263-265 through control lines 276. Controller 275 is also connected through lines 277 to control valves 295-297 and is able to measure and control pressure in chambers 260-262 by opening valves 295-297, which lead to vacuum 298. A purge gas supplied by a purge gas supply 280 is used to purge run/refill chambers 255-257. In some embodiments, the precursors 120 and 121 are transported under a vapor draw configuration.

In some embodiments, the carrier gas supply 270 is removed from the system 400. In some embodiments, a mass flow controller (MFC) (not shown) is added to the delivery line 199 located between the run/refill chamber 255 and the deposition chamber 260.

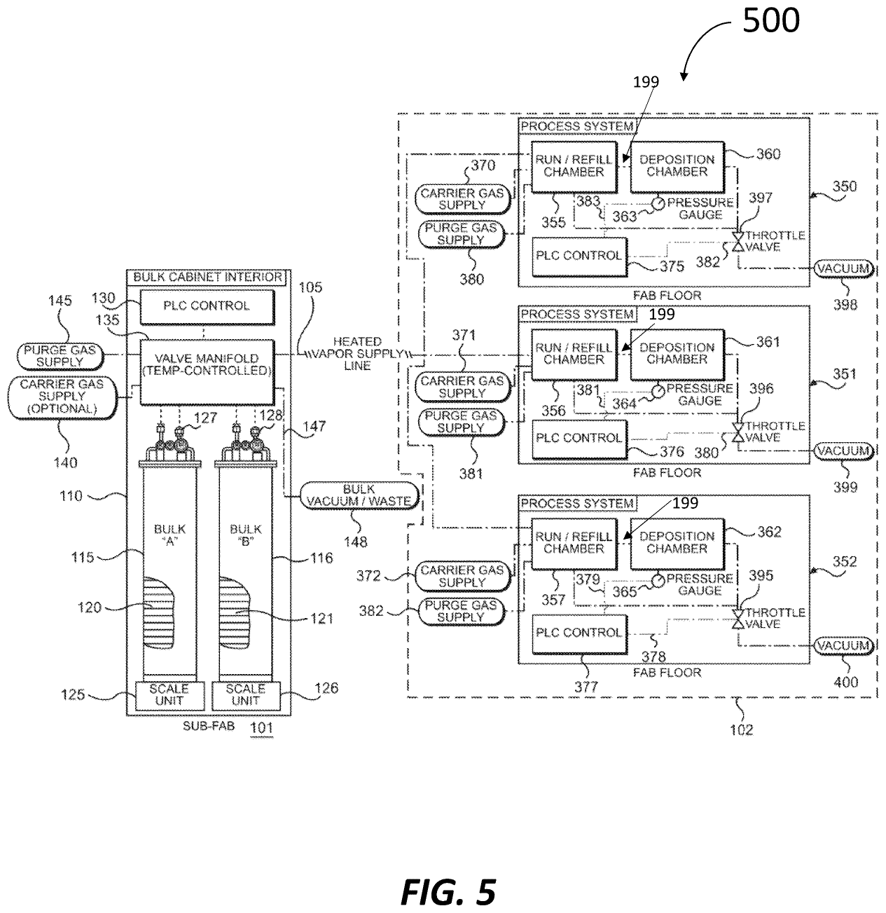

FIG. 5 is a schematic diagram of another exemplary system 500 including at least one conduit as described herein according to the various embodiments. System 500 generally functions in the same manner as systems 300 and 400 except that system 500 includes a plurality of process systems 350-352. Each process system 350-352 includes a run/refill chamber 355-357, which receives precursors 120 and 121 from conduit 105 (vapor supply line). In some embodiments, conduit 105 can be a coated conduit as described herein. The conditions of the first conduit 105 can include any of the conditions disclosed herein and generally include a temperature and/or a pressure that is less than a temperature and/or a pressure of line 199. Precursors 120 and 121 enter run/refill chambers 355-357 as a vapor and are then deposited within run/refill chambers 355-357 as a solid by cooling run/refill chambers 355-357. When needed, precursor 120 or 121 is sublimated within one of run/refill chambers 355-357 by heating that run/refill chamber 355-357. Precursor 120 or 121 is then transported to a corresponding deposition chamber 360-362 via lines 199. Precursor 120 or 121 is used to deposit a film on a substrate (not shown) located within that deposition chamber 360-362. Optional carrier gas supplies 370-372 can be used to transport precursors 120 and 121 within process systems 350-352, while controllers 375-377 control process systems 350-352. More specifically, controllers 375-377 are connected to gauges 363-365 through control lines of which lines 378-383 are labeled. Controllers 375-377 are also connected to control valves 395-397 and are able to measure and control pressure in chambers 360-362 by opening valves 395-397, which lead to vacuum at 398-400. A purge gas supplied by purge gas supplies 380-382 is used to purge run/refill chambers 355-357. In some embodiments, the precursors 120 and 121 are transported under a vapor draw configuration.

### EXAMPLES

### Example 1

In a first experiment, ozone gas was generated from a 20% N₂/80% O₂ mixture and flowed through a coated and an uncoated (bare) 316L stainless steel test coil. Both the coated and uncoated test coils had a ¼ in (6.35 mm) outer diameter and were 20 ft (6.096 m) in length. The inner surface of the coated test coil was coated with alumina. Two sets of three runs each were conducted for each of the coated and uncoated stainless steel coil. The ozone gas was collected in an impinger containing 1% nitric acid and the liquid analyzed for metals using inductively coupled plasma mass spectrometry (ICP-MS). The results for each run are presented in Table 1. The results are normalized for run time.

TABLE 1

| | Exposure | | |
|---|---|---|---|
| Sample | Time (hrs) | Cr (ppb/hr) | Mn (ppb/hr) |
| Uncoated 1-1 | 8 | 4.175 | 0.400 |
| Uncoated 1-2 | 14.25 | 1.712 | 0.113 |
| Uncoated 1-3 | 20.25 | 4.917 | 0.525 |
| Uncoated 2-1 | 8 | 4.175 | 0.396 |
| Uncoated 2-2 | 14.25 | 1.712 | 0.118 |
| Uncoated 2-3 | 20.25 | 4.717 | 0.505 |
| Coated 1-1 | 5 | 0.100 | 0.100 |
| Coated 1-2 | 11 | 0.083 | 0.083 |
| Coated 1-3 | 17 | 0.315 | 0.083 |
| Coated 2-1 | 5 | 0.100 | 0.100 |
| Coated 2-2 | 11 | 0.083 | 0.083 |
| Coated 2-3 | 17 | 0.305 | 0.083 |

Chromium (Cr) and Manganese (Mn) impurities were detectable and higher when ozone was passed through the uncoated stainless steel coil as compared to the coated stainless steel coil. For the uncoated coil, the average values for chromium and manganese measured in the gas stream were 3.67 ppb/hr and 0.34 ppb/hr, respectively. For the coated coil, the average values for chromium and manganese in the gas stream was 0.16 ppb/hr and 0.089 ppb/hr. Based on the average values, the data shows a 95% reduction in chromium impurities and a 74% reduction in manganese impurities in an ozone gas stream when ozone is flowed through a coated stainless steel coil. This indicates that coating the inner surface of a stainless steel line may mitigate risk of metal line corrosion for stainless steel lines exposed to ozone gas.

### Example 2

In a second experiment, MoO2Cl2 vapor was flowed through a coated and an uncoated (bare) 316L stainless steel test line. Each of coated and uncoated lines the same outer diameter and length. The inner surface of the coated line was coated with alumina. The MoO2Cl2 vapor was collected in an impinger and the liquid analyzed for iron and chromium impurities using inductively coupled plasma mass spectrometry (ICP-MS). The testing was repeated at three different temperatures simulating process conditions at a high temperature range at a control temperature (20° C.). The results are presented in Table 2

TABLE 2

| Sample | Temperature | Fe (ppm) | Cr (ppm) |
|---|---|---|---|
| Uncoated SS-1 | Control | 0.421 | 0.01 |
| Uncoated SS-2 | 140° C. | 0.021 | 0.01 |
| Uncoated SS-3 | 160° C. | 0.01 | 0.01 |
| Uncoated SS-4 | 180° C. | 0.126 | 0.01 |
| Coated SS-1 | Control | 0.014 | 0.01 |
| Coated SS-2 | 140° C. | 0.02 | 0.01 |
| Coated SS-3 | 160° C. | 0.01 | 0.01 |
| Coated SS-4 | 180° C. | 0.058 | 0.01 |

Iron (Fe) impurities were detectable and higher when MoO2Cl2 vapor was passed through the uncoated stainless steel line as compared to the coated stainless steel line. For the uncoated line, the average value for iron impurities detected in the vapor was 0.15 ppm. For the coated line, the average value for iron impurities detected in the vapor stream was 0.03 ppm. The data shows an 80% reduction in iron impurities detected in a MoO2Cl2 vapor stream when MoO2Cl2 vapor is flowed through a coated stainless steel coil. This indicates that coating the inner surface of a stainless steel line may appear mitigate risk of metal contamination from iron impurities when the metal line is exposed to MoO2Cl2 vapor.

### Aspects

Various Aspects are described below. It is to be understood that any one or more of the features recited in the following Aspect(s) can be combined with any one or more other Aspect(s).

Aspect 1 relates to a system comprising: a first subsystem, wherein the first subsystem is located in a sub-fabrication area of a semiconductor manufacturing facility; a second subsystem, wherein the second subsystem is located in a fabrication area of the semiconductor manufacturing facility; and a coated conduit connecting the first subsystem to the second subsystem, the conduit having an inner surface, an outer surface, and a protective coating deposited on and covering the inner surface, wherein when a gas or vapor is flowed through the coated conduit having the protective coating, the gas or vapor shows at least a 50% reduction in a metal impurity compared to when the gas or vapor is flowed through an uncoated conduit having no protective coating.

Aspect 2 include includes the system of Aspect 1, wherein the coated conduit is a gas line for carrying a process gas from the first subsystem to the second system.

Aspect 3 includes the system of Aspect 1 or Aspect 2, wherein the coated conduit fluidly connects at least one container of the first subsystem to at least one container of the second subsystem.

Aspect 4 includes the system of any one of Aspects 1-3, wherein a distance between an inlet of the coated conduit and an outlet of the coated conduit is at least 2.5 m.

Aspect 5 includes the system of any one of Aspects 1-4, wherein a distance between an inlet of the coated conduit and an outlet of the coated conduit ranges from 2.5 m to 500 m.

Aspect 6 includes the system of any one of Aspects 1-5, wherein a ratio of a length of the coated conduit to a width of a cross-section of the coated conduit ranges from 2:1 to 1000:1.

Aspect 7 includes the system of any one of Aspects 1-6, wherein the protective coating covers at least 99.999% of the inner surface of the coated conduit.

Aspect 8 includes he system of any one of Aspects 1-7, wherein the protective coating does not cover an outer surface of the coated conduit.

Aspect 9 includes the system of any one of Aspects 1-8, wherein the protective coating comprises at least one of yttria, alumina, or any combination thereof.

Aspect 10 includes system of any one of Aspects 1-9, wherein the coating has an average thickness ranging from 5 nm to 250 nm.

Aspect 11 includes the system of any one of Aspects 1-10, wherein the protective coating is an atomic layer deposited (ALD) coating directly contacting the inner surface of the conduit.

Aspect 12 includes the system of any one of Aspects 1-11, wherein the gas or vapor is ozone gas.

Aspect 13 includes the system of any one of Aspects 1-11, wherein the gas or vapor is MoO2Cl2 vapor.

Aspect 14 includes the system of Aspect 12, wherein when ozone gas is flowed through the coated conduit having the protective coating, the ozone gas shows at least a 50% reduction in a chromium impurity compared to when ozone gas is flowed through an uncoated conduit having no protective coating.

Aspect 15 includes the system of any one of Aspects 12 or 14, wherein when ozone gas is flowed through the coated conduit having the protective coating, the ozone gas shows at least a 50% reduction in a manganese impurity compared to when ozone gas is flowed through an uncoated conduit having no protective coating.

Aspect 16 includes the system of Aspect 13, wherein when MoO2Cl2 vapor is flowed through the coated conduit having the protective coating, the MoO2Cl2 vapor shows at least a 50% reduction in an iron impurity compared to when MoO2Cl2 vapor is flowed through an uncoated conduit having no protective coating.

Aspect 17 is a method comprising: obtaining a conduit, wherein the conduit has an inlet, an outlet, an inner surface, and an outer surface; applying a pretreatment to a vapor-exposed surface portion of the inner surface of the conduit; and forming a protective coating on the vapor-exposed portion of the inner surface of the conduit via atomic layer deposition (ALD).

Aspect 18 includes the method of Aspect 17, wherein applying the pretreatment comprises physically removing at least one substance from the inner surface of the conduit.

Aspect 19 includes the method of Aspect 17, wherein applying the pretreatment comprises chemically removing at least one substance from the inner surface of the conduit.

Aspect 20 includes the method of Aspect 17, wherein forming the protective coating comprises flowing a vapor precursor through the conduit.

Aspect 21 includes the method of Aspect 20, wherein forming the protective coating further comprises flowing a co-reactant precursor through the conduit.

Aspect 22 includes the method of Aspect 17, further comprising: after forming the protective coating, applying a force to the conduit sufficient to bend at least a portion of the conduit.

Aspect 23 includes the method of any one of Aspects 17-22, wherein when a gas or vapor is flowed through the conduit having the protective coating formed on a vapor-exposed portion of its inner surface, the gas or vapor shows at least a 50% reduction in a metal impurity compared to when the gas or vapor is flowed through an uncoated conduit having no protective coating.

Aspect 24 An article comprising: a coated conduit, wherein the coated conduit is configured to connect a first subsystem to a second subsystem; wherein the first subsystem is located in a sub-fabrication area of a semiconductor manufacturing facility; wherein the second subsystem is located in a fabrication area of the semiconductor manufacturing facility; wherein the coated conduit has an inner surface and an outer surface; and a protective coated deposited on and covering the inner surface; and wherein when a gas or vapor is flowed through the coated conduit having the protective coating, the gas or vapor shows at least a 50% reduction in a metal impurity compared to when the gas or vapor is flowed through an uncoated conduit having no protective coating.

Aspect 25 includes the system of Aspect 24, wherein the coated conduit is a gas line for carrying a process gas from the first subsystem to the second system.

Aspect 26 includes the system of Aspect 24 or Aspect 25, wherein the coated conduit fluidly connects at least one container of the first subsystem to at least one container of the second subsystem.

Aspect 27 includes the system of any one of Aspects 24-26, wherein a distance between an inlet of the coated conduit and an outlet of the coated conduit is at least 2.5 m.

Aspect 28 includes the system of any one of Aspects 24-27, wherein a distance between an inlet of the coated conduit and an outlet of the coated conduit ranges from 2.5 m to 500 m.

Aspect 29 includes the system of any one of Aspects 24-28, wherein a ratio of a length of the coated conduit to a width of a cross-section of the coated conduit ranges from 2:1 to 1000:1.

Aspect 30 includes the system of any one of Aspects 24-29, wherein the protective coating covers at least 99.999% of the inner surface of the coated conduit.

Aspect 31 includes the system of any one of Aspects 24-30, wherein the protective coating does not cover an outer surface of the coated conduit.

Aspect 32 includes the system of any one of Aspects 24-31, wherein the protective coating comprises at least one of yttria, alumina, or any combination thereof.

Aspect 33 includes the system of any one of Aspects 24-32, wherein the coating has an average thickness ranging from 5 nm to 250 nm.

Aspect 34 includes the system of any one of Aspects 24-32, wherein the protective coating is an atomic layer deposited (ALD) coating directly contacting the inner surface of the conduit.

Aspect 35 includes the system of any one of Aspects 24-31, wherein the gas or vapor is ozone gas.

Aspect 36 includes the system of any one of Aspects 24-31, wherein the gas or vapor is MoO2Cl2 vapor.

Aspect 37 includes the system of Aspect 35, wherein when ozone gas is flowed through the coated conduit having the protective coating, the ozone gas shows at least a 50% reduction in a chromium impurity compared to when ozone gas is flowed through an uncoated conduit having no protective coating.

Aspect 38 includes the system of any one of Aspects 35 or 37, wherein when ozone gas is flowed through the coated conduit having the protective coating, the ozone gas shows at least a 50% reduction in a manganese impurity compared to when ozone gas is flowed through an uncoated conduit having no protective coating.

Aspect 39 includes the system of Aspect 36, wherein when MoO2Cl2 vapor is flowed through the coated conduit having the protective coating, the MoO2Cl2 vapor shows at least a 50% reduction in an iron impurity compared to when MoO2Cl2 vapor is flowed through an uncoated conduit having no protective coating.

Aspect 40 relates to a method comprising: flowing MoO2Cl2 vapor through a coated conduit from an inlet to an outlet, the conduit having a continuous protective coating covering an inner surface of the conduit, wherein when a gas or vapor is flowed through the coated conduit having the protective coating, the gas or vapor shows at least a 50% reduction in a metal impurity compared to when the gas or vapor is flowed through an uncoated conduit having no protective coating.

Aspect 41 relates to a system for delivering a process gas comprising: a delivery vessel containing MoO2Cl2; and a coated conduit for delivering MoO2Cl2 vapor to a process tool coupled to the delivery vessel, wherein the coated conduit extends from an inlet connected to the delivery vessel to an outlet, the coated conduit having an inner surface and an outer surface; and a protective coating deposited on and covering the inner surface, wherein MoO2Cl2 vapor collected at the outlet of the coated conduit shows at least a 50% reduction in a metal impurity compared to MoO2Cl2 vapor that is flowed through and collected at an outlet of an uncoated conduit having no protective coating.

Aspect 42 includes the system of Aspect 41, wherein the length of the conduit is at least 2.5 m.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A system comprising:
a first subsystem,
wherein the first subsystem is located in a sub-fabrication area of a semiconductor manufacturing facility;
a second subsystem,
wherein the second subsystem is located in a fabrication area of the semiconductor manufacturing facility; and
a coated conduit connecting the first subsystem to the second subsystem, the conduit having an inner surface, an outer surface, and a protective coating deposited on and covering the inner surface,
wherein when a gas or vapor is flowed through the coated conduit having the protective coating, the gas or vapor shows at least a 50% reduction in a metal impurity detected in the gas or vapor compared to when the gas or vapor is flowed through an uncoated conduit having no protective coating.

2. The system of claim 1, wherein the coated conduit is a gas line for carrying a process gas from the first subsystem to the second system.

3. The system of claim 1, wherein the coated conduit fluidly connects at least one container of the first subsystem to at least one container of the second subsystem.

4. The system of claim 1, wherein a distance between an inlet of the coated conduit and an outlet of the coated conduit is at least 2.5 m.

5. The system of claim 1, wherein a ratio of a length of the coated conduit to a width of a cross-section of the coated conduit ranges from 2:1 to 1000:1.

6. The system of claim 1, wherein the protective coating covers at least 99.999% of the inner surface of the coated conduit.

7. The system of claim 1, wherein the protective coating comprises at least one of yttria, alumina, or any combination thereof.

8. The system of claim 1, wherein when ozone gas is flowed through the coated conduit having the protective coating, the ozone gas shows at least a 50% reduction in a chromium impurity detected in the ozone gas compared to when ozone gas is flowed through an uncoated conduit having no protective coating.

9. The system of claim 1, wherein when ozone gas is flowed through the coated conduit having the protective coating, the ozone gas shows at least a 50% reduction in a manganese impurity detected in the ozone gas compared to when ozone gas is flowed through an uncoated conduit having no protective coating.

10. The system of claim 1, wherein when MoO2Cl2 vapor is flowed through the coated conduit having the protective coating, the MoO2Cl2 vapor shows at least a 50% reduction in an iron impurity detected in the MoO2Cl2 vapor compared to when MoO2Cl2 vapor is flowed through an uncoated conduit having no protective coating.

11. A method comprising:
forming a protective coating on an inner surface of a conduit via atomic layer deposition (ALD), the conduit having a length extending from an outlet to an inlet of the conduit of at least 2.5 m.

12. The method of claim 11, further comprising:
after forming the protective coating, applying a force to the conduit sufficient to bend at least a portion of the conduit.

13. The method of claim 11, further comprising flowing a gas or vapor through the conduit having the protective coating formed on its inner surface, and collecting the gas or vapor that is flowed through the conduit at the outlet of the conduit, wherein the gas or vapor collected at the outlet shows at least a 50% reduction in a metal impurity compared to when the gas or vapor is flowed through an uncoated conduit having no protective coating.

14. An article comprising:
a coated conduit,
wherein the coated conduit extends from an inlet to an outlet, the coated conduit having an inner surface and an outer surface; and a protective coating deposited on and covering the inner surface; and
wherein when a gas or vapor is flowed through the coated conduit having the protective coating, the gas or vapor shows at least a 50% reduction in a metal impurity compared to when the gas or vapor is flowed through an uncoated conduit having no protective coating.

15. The system of claim 14, wherein the coated conduit is a gas line for carrying a process gas from the first subsystem to the second system.

16. The system of claim 14, wherein a distance between an inlet of the coated conduit and an outlet of the coated conduit is at least 2.5 m.

17. The system of claim 14, wherein the protective coating comprises at least one of yttria, alumina, or any combination thereof.

18. The system of claim 14, wherein when ozone gas is flowed through the coated conduit having the protective coating, the ozone gas shows at least a 50% reduction in a chromium impurity compared to when ozone gas is flowed through an uncoated conduit having no protective coating.

19. The system of claim 14, wherein when ozone gas is flowed through the coated conduit having the protective coating, the ozone gas shows at least a 50% reduction in a manganese impurity compared to when ozone gas is flowed through an uncoated conduit having no protective coating.

20. The system of claim 14, wherein when MoO2Cl2 vapor is flowed through the coated conduit having the protective coating, the MoO2Cl2 vapor shows at least a 50% reduction in an iron impurity compared to when MoO2Cl2 vapor is flowed through an uncoated conduit having no protective coating.
